(19) United States
(12) Patent Application Publication
(10) Pub. No.: US 2017/0200818 A1
(43) Pub. Date: Jul. 13, 2017

(54) SEMICONDUCTOR DEVICE

(71) Applicant: KABUSHIKI KAISHA TOSHIBA, Tokyo (JP)

(72) Inventors: Yoshikazu SUZUKI, Komatsu Ishikawa (JP); Tasuku ONO, Nonoichi Ishikawa (JP)

(21) Appl. No.: 15/231,361

(22) Filed: Aug. 8, 2016

(30) Foreign Application Priority Data
Jan. 8, 2016 (JP) 2016002680

(51) Int. Cl. H01L 29/778; H01L 29/20; H01L 29/40

(52) U.S. Cl. CPC H01L 29/7787; H01L 29/404; H01L 29/2003

(57) ABSTRACT

A semiconductor device includes a first nitride semiconductor layer, a second nitride semiconductor layer on the first nitride semiconductor layer and having a larger band gap than that of the first nitride semiconductor layer, a gate electrode on the second nitride semiconductor layer, drain and source electrodes on the second nitride semiconductor layer with the gate electrode interposed therebetween, interlayer insulating films on the second nitride semiconductor layer in a layer shape, and field plates including a first field plate at a greater distance from the second nitride semiconductor layer than the gate electrode and closer to the drain electrode than the gate electrode, and a second field plate at a larger distance from the second nitride semiconductor layer than the first field plate and nearer to drain electrode than the first field plate. The first and second field plates extend inwardly of the same interlayer insulating film.

### CROSS-REFERENCE TO RELATED APPLICATION

This application is based upon and claims the benefit of priority from Japanese Patent Application No. 2016-002680, filed Jan. 8, 2016, the entire contents of which are incorporated herein by reference.

### FIELD

Embodiments described herein relate generally to a semiconductor device.

### BACKGROUND

As an example of a semiconductor device, a horizontal structure field-effect transistor is known. In the horizontal structure field-effect transistor, a drain electrode is provided on an upper side of the semiconductor layer as are the source electrode and the gate electrode.

When a high voltage is applied between the drain electrode and the source electrode in the horizontal structure field-effect transistor, an electric field concentration occurs between the gate electrode and the drain electrode. Therefore, when the semiconductor layer is formed by, for example, two nitride semiconductor layers having different band gaps, there is a possibility that electrons in the two dimensional electron gas generated in the interface of the two nitride semiconductor layers may be trapped. As the result, a phenomenon of increasing ON-resistance in the field-effect transistor or a so-called current collapse phenomenon may occur.

As a way of reducing the electric field concentration, there is known a technique of forming field plates in a step pattern between the gate electrode and the drain electrode. According to this technique, generally, each field plate is formed on a separate interlayer insulating film. Therefore, when there are many field plates in the step pattern, the number of the interfaces between required multiple interlayer insulating films is increased. Since the electrons of the two dimensional electron gas are easily trapped in the interface between the interlayer insulating films, there is a concern that the suppression effect on the current collapse phenomenon may be insufficient when there are many interlayer insulating films.

### DESCRIPTION OF THE DRAWINGS

FIG. 1 is a cross-sectional view showing a schematic structure of a semiconductor device according to an embodiment.

FIG. 2 is a top plan view showing a schematic structure of the semiconductor device according to the embodiment.

FIGS. 3A to 3E are cross-sectional views each showing a result of a part of the manufacturing process of the semiconductor device according to the embodiment.

FIGS. 4A to 4E are cross-sectional views each showing a result of a part of the manufacturing process after the process result shown in FIG. 3E.

FIGS. 5A to 5E are cross-sectional views each showing a result of a part of the manufacturing process after the process result shown in FIG. 4E.

FIG. 6 is a cross-sectional view showing a schematic structure of a semiconductor device according to a modified example 1.

FIG. 7 is a cross-sectional view showing a schematic structure of a semiconductor device according to a modified example 2.

FIG. 8 is a cross-sectional view showing a schematic structure of a semiconductor device according to a modified example 3.

### DETAILED DESCRIPTION

According to embodiments, there is provided a semiconductor device having a suppressed current collapse phenomenon.

In general, according to one embodiment, a semiconductor device includes: a first nitride semiconductor layer; a second nitride semiconductor layer with a larger band gap than that of the first nitride semiconductor layer provided on the first nitride semiconductor layer; a gate electrode provided on the second nitride semiconductor layer; a drain electrode and a source electrode provided on the second nitride semiconductor layer with the gate electrode interposed therebetween; a plurality of interlayer insulating films provided on the second nitride semiconductor layer in a layer shape; and a plurality of field plates including a first field plate that is provided at a greater distance from the second nitride semiconductor layer than the gate electrode and closer to the drain electrode than the gate electrode and a second field plate that is provided at a larger distance from the second nitride semiconductor layer than the first field plate and nearer to drain electrode than the first field plate. The first field plate and the second field plate extend inwardly of the same interlayer insulating film.

Hereinafter, embodiments will be described with reference to the drawings. The embodiments are not to restrict the disclosure.

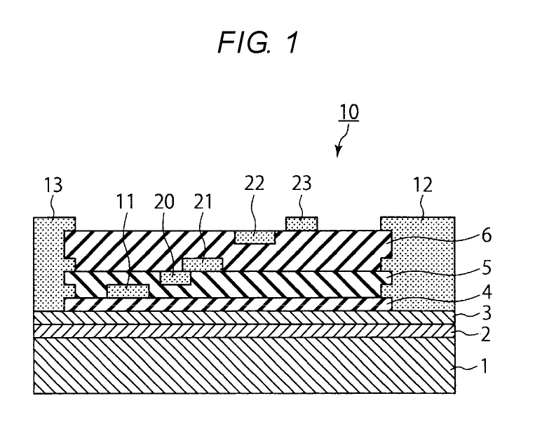

FIG. 1 is a cross-sectional view showing a schematic sectional view of a structure of a semiconductor device according to the embodiment. As illustrated in FIG. 1, a semiconductor device 10 according to the embodiment includes a substrate 1, a first nitride semiconductor layer 2, a second nitride semiconductor layer 3, a gate insulating film 4, a plurality of interlayer insulating films 5 and 6, a gate electrode 11, a drain electrode 12, a source electrode 13, and a plurality of field plates 20 to 23.

The substrate 1 is formed of, for example, silicon, silicon nitride (SiN), or sapphire. On the substrate 1, there is provided a relaxation layer (not illustrated) for relaxing the mismatch of the lattice constants of the first nitride semiconductor layer 2 and the substrate 1.

The first nitride semiconductor layer 2 is provided on the relaxation layer and is formed of, for example, gallium nitride (GaN).

The second nitride semiconductor layer 3 is provided on the first nitride semiconductor layer 2. The second nitride semiconductor layer 3 is formed of a compound with a larger band gap than that of the first nitride semiconductor layer 2, for example, AlGaN (aluminum gallium nitride).

The gate insulating film 4 is provided on the second nitride semiconductor layer 3. The gate insulating film 4 is formed of, for example, silicon nitride, silicon oxide (SiO₂), or aluminum oxide (Al₂O₃). The gate insulating film 4 may not be provided.

The interlayer insulating films 5 and 6 are provided on the gate insulating film 4 in layers. In the embodiment, the interlayer insulating film 5 is provided on the gate insulating film 4 to cover the gate electrode 11 as a first interlayer insulating film, while the interlayer insulating film 6 is provided on the interlayer insulating film 5 as a second interlayer insulating film.

The gate electrode 11 is provided on the gate insulating film 4. The drain electrode 12 and the source electrode 13 are formed on the second nitride semiconductor layer 3 and spaced from each other with the gate insulating film 4 interposed therebetween. When the gate insulating film 4 is not provided, the gate electrode 11 is in contact with the second nitride semiconductor layer 3. In other words, the gate electrode 11 can be provided on the second nitride semiconductor layer 3 without interposing the gate insulating film 4 therebetween. In the disclosure, the “gate electrode 11 provided on the second nitride semiconductor layer 3” includes the form of the gate electrode 11 indirectly provided on the second nitride semiconductor layer 3 through the gate insulating film 4 and the form of the gate electrode 11 directly provided on the second nitride semiconductor layer 3.

The field plate 20 is covered with the interlayer insulating film 5. The field plate 20 is provided at a greater distance from the second nitride semiconductor layer 3 than is the gate electrode 11 and closer to the drain electrode 12 than is the gate electrode 11. In short, the field plate 20 is provided in an upper step than the location of the gate electrode 11.

The field plate 21 forms a first field plate and is covered with the interlayer insulating film 6. The field plate 21 is provided at a greater distance from the second nitride semiconductor layer 3 than is the field plate 20 (the gate electrode 11) and nearer to the drain electrode 12 than is the field plate 20 (the gate electrode 11). In short, the field plate 21 is provided in an upper step than that of the field plate 20 (the gate electrode 11). In the embodiment, a part of the field plate 21 overlaps and contacts the field plate 20 and thus the electrical potential of each are identical.

The field plate 22 forms a second field plate and is embedded in the same interlayer insulating film 6 as is the field plate 21. The field plate 22 is provided at a greater distance from the second nitride semiconductor layer 3 than is the field plate 21 and closer to the drain electrode 12 than is the field plate 21. In short, the field plate 22 is provided in a yet more upper step than is the field plate 21.

The field plate 23 is provided on the upper surface of the interlayer insulating film 6. The field plate 23 is provided at a greater distance from the second nitride semiconductor layer 3 than is the field plate 22 and closer to the drain electrode 12 than is the field plate 22. In short, the field plate 23 is provided in a yet more upper step than is the field plate 22.

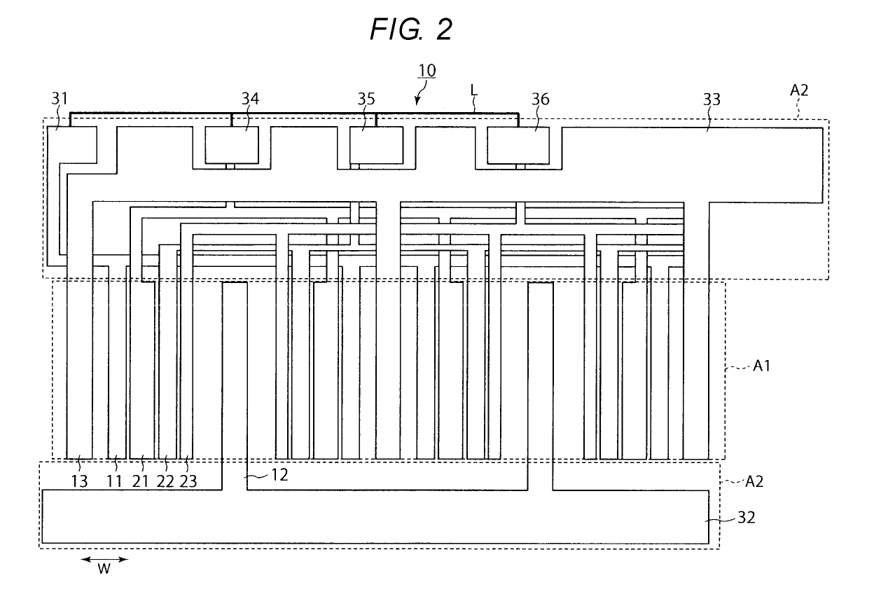

FIG. 2 is a top plan view showing a schematic structure of the semiconductor device according to the embodiment. As illustrated in FIG. 2, the semiconductor device 10 according to the embodiment includes an active region A1 and inactive regions A2 positioned outside of the active region A1. The active region A1 is provided with the above mentioned components, specifically, the substrate 1, the first nitride semiconductor layer 2, the second nitride semiconductor layer 3, the gate insulating film 4, the interlayer insulating films 5 and 6, the gate electrode 11, the drain electrode 12, the source electrode 13, and the field plates 20 to 23.

On the other hand, the inactive region A2 is provided with a gate pad 31, a drain pad 32, a source pad 33, and a plurality of field plate pads 34, 35 and 36.

The gate pad 31 is electrically coupled to the gate electrode 11. The drain pad 32 is electrically coupled to the drain electrode 12. The source pad 33 is electrically coupled to the source electrode 13.

The plurality of field plate pads 34 to 36 are electrically coupled to one of the field plates 20 to 23. In the embodiment, the field plates 20 and 21 are electrically coupled to the field plate pad 34, the field plate 22 is electrically coupled to the field plate pad 35, and the field plate 23 is electrically coupled to the field plate pad 36.

As illustrated in FIG. 2, in the embodiment, the potential of the field plate pads 34, 35 and 36 is the same as the potential of the gate pad 31 because they are interconnected by the wiring L. However, the potential of each field plate pad may be the same as the potential of the source pad 33 or may be a floating potential if wiring L is not provided. Here, a floating potential means a state in which each field plate pad is not electrically coupled to any of the gate pad 31, the drain pad 32, or the source pad 33. The wiring L may be a bonding wire provided within a package of the semiconductor device 1 or a lead wire provided outside of the package.

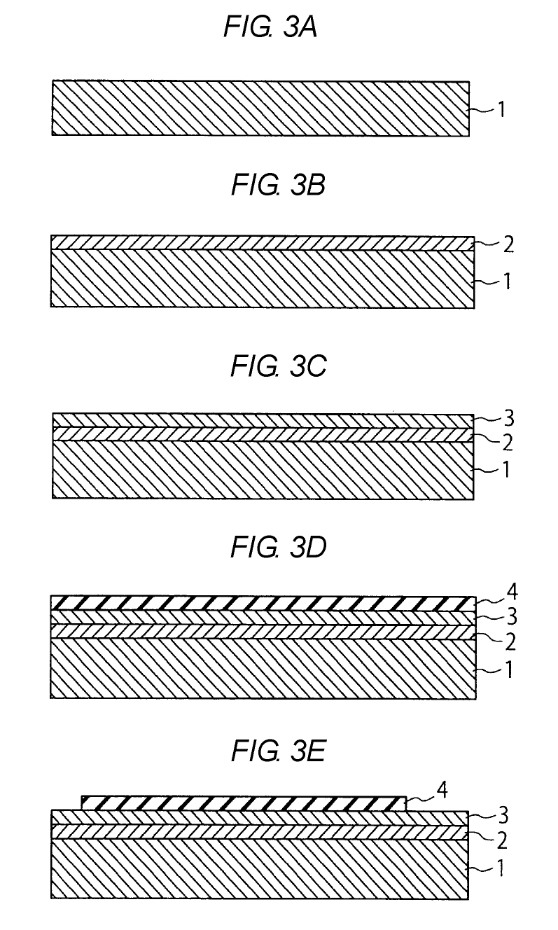

Hereinafter, the manufacturing process of the semiconductor device 1 according to the embodiment will be described with reference to FIGS. 3A to 5E.

As illustrated in FIG. 3A, the substrate 1 is formed. The substrate 1 includes a relaxing layer (not illustrated) as mentioned above. After forming or providing the substrate 1, as illustrated in FIG. 3B, the first nitride semiconductor layer 2 is formed on the substrate 1. Consequently, as illustrated in FIG. 3C, the process of forming the second nitride semiconductor layer 3 on the first nitride semiconductor layer 2 is performed.

After forming the second nitride semiconductor layer 3, as illustrated in FIG. 3D, the gate insulating film 4 is formed on the second nitride semiconductor layer 3. Here, the gate insulating film 4 is formed to cover the whole top surface of the second nitride semiconductor layer 3. Thereafter, as illustrated in FIG. 3E, the opposed end portions of the gate insulating film 4 are removed through etching. As a result of the etching, the opposed end portions of the second nitride semiconductor layer 3 are exposed.

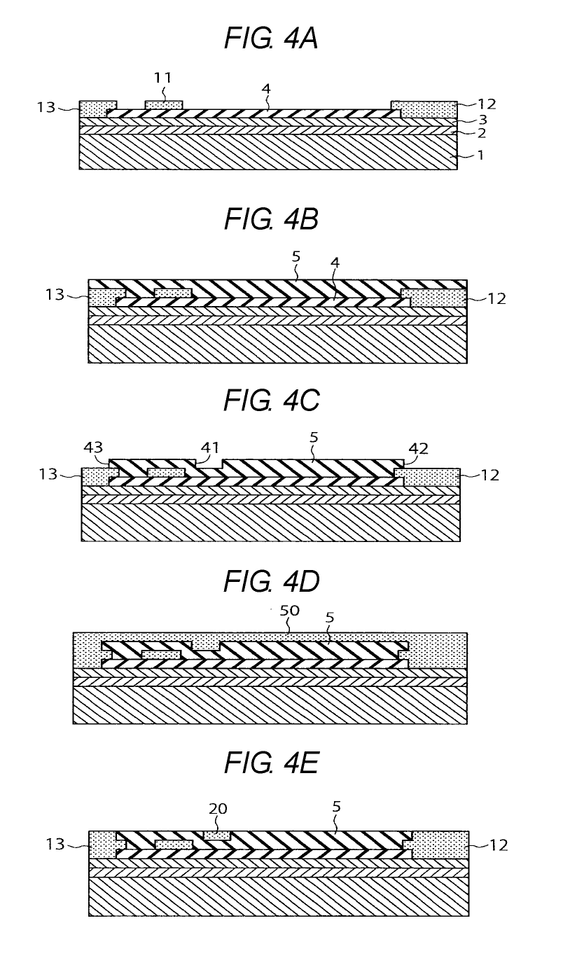

A portion of the drain electrode 12 and a portion of the source electrode 13 are formed on the opposed exposed end portions of the second nitride semiconductor layer 3, as illustrated in FIG. 4A. At the same time, the gate electrode 11 is formed on the gate insulating film 4.

After forming each electrode, as illustrated in FIG. 4B, the interlayer insulating film 5 is formed. Here, the interlayer insulating film 5 is formed to cover not only the gate electrode 11 but also the drain electrode 12 and the source electrode 13. Then, as illustrated in FIG. 4C, a portion of the interlayer insulating film 5 is removed by the etching and as the result, a recess formed as a trench 41 and contact openings 42 and 43 are formed. The trench 41 is formed by etching into the top surface of the interlayer insulating film 5 and the contact openings 42 and 43 are formed to expose the drain electrode 12 and the source electrode 13, respectively.

A conductive member 50 is embedded in the trench 41 and in the contact openings 42 and 43, as illustrated in FIG. 4D. As the conductive member 50, for example, aluminum (Al), alloy of aluminum and copper (Al Cu), and gold (Au) can be used. Thereafter, as illustrated in FIG. 4E,removing an extraneous portion of the conductive member 50 extending above the first interlayer insulating film 4 is performed by polishing. As a result, the field plate 20 is formed within the trench 41.

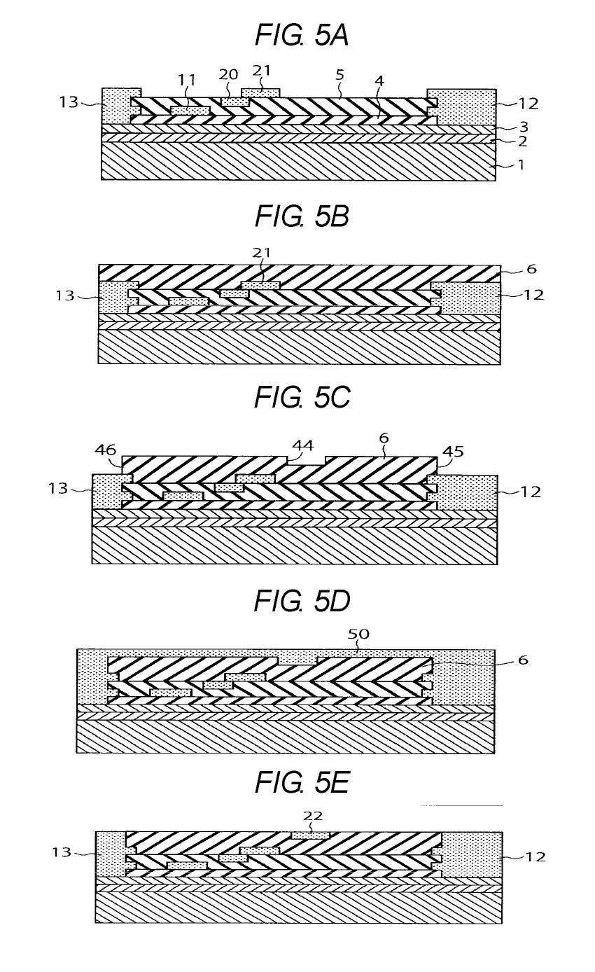

Consequently, as illustrated in FIG. 5A, the field plate 21 is formed on the interlayer insulating film 5. Then, as illustrated in FIG. 5B, the interlayer insulating film 6 is formed. Here, the interlayer insulating film 6 is formed to cover not only the field plate 21 but also the drain electrode 12 and the source electrode 13. Then, as illustrated in FIG. 5C, a part of the interlayer insulating film 6 is removed by etching and as the result, a recess formed as a trench 44 and contact openings 45 and 46 are formed. The trench 45 is formed by etching into the top surface of the interlayer insulating film 6 and the contact openings 45 and 46 are formed to expose the drain electrode 12 and the source electrode 13, respectively.

The conductive member 50 is again embedded into the trench 44 and the contact holes 45 and 46, as illustrated in FIG. 5D. Then, as illustrated in FIG. 5E, an extraneous portion of the conductive member 50 is removed by polishing. As a result, the field plate 22 is formed within the trench 44. Then, as shown in FIG. 1, the field plate 23 is formed on the interlayer insulating film 6.

According to the semiconductor device 1 in the above mentioned embodiment, the field plate 22 and the field plate 23 are arranged in a stepped shape but a separate interlayer insulating film does not exist between them. This is because the trench 44 is formed in the top surface of the interlayer insulating film 6 and the field plate 22 is formed within the trench 44. As a result, the number of interfaces of adjoining interlayer insulating film is less than the number of the steps of the field plates, which can improve the suppression effect on the current collapse phenomenon.

### Modified Example 1

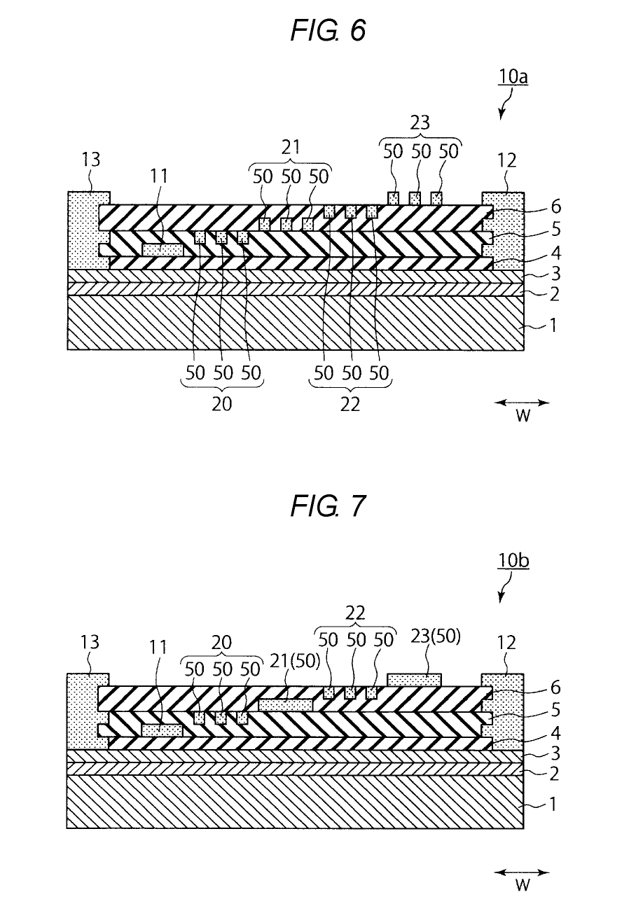

FIG. 6 is a cross-sectional view showing a schematic structure of a semiconductor device according to a modified example 1. In FIG. 6, the same reference numerals are given to the same components as those of the semiconductor device 1 and a further detailed description thereof is omitted.

As illustrated in FIG. 6, in the semiconductor device 10a according to the modified example 1, each of the field plates 20 to 23 is formed of a plurality of conductive members 50, i.e., a plurality of sub-plates, and the conductive members 50 are arranged side by side in the width direction W (also refer to FIG. 2) of the semiconductor device 10a.

In the field plate 20, the two conductive members 50 positioned closest to the source electrode 13 are electrically coupled to the gate pad 31 and the remaining one conductive member 50 is electrically coupled to the field plate pad 34.

In the field plate 21, the two conductive members 50 closest to the source electrode 13 are electrically coupled to the field plate pad 34 and the remaining one conductive member 50 is electrically coupled to the field plate pad 35.

In the field plate 22, the two conductive members 50 closest to the source electrode 13 are electrically coupled to the field plate pad 35, and the remaining one conductive member 50 is electrically coupled to the field plate pad 36.

The three conductive members 50 forming the field plate 23 are also electrically coupled to the field plate pad 36.

In the modified example 1, the width and the thickness of the plural conductive members 50 are identical. Therefore, when forming the field plates 20 and 22, a plurality of trenches 41 and 44 with the same opening width and depth are formed and the conductive member 50 is embedded within the trenches. On the other hand, also when forming the field plates 21 and 23, the plural conductive members 50 with the same width and thickness are formed on the interlayer insulating films 5 and 6.

According to the semiconductor device 10a in the above mentioned modified example 1, there separate interlayer insulating film between the field plate 22 and the field plate 23, similarly to the above mentioned semiconductor device 10. According to this, also in the modified example 1, the number of the interfaces between interlayer insulating films is less than the number of the steps of the field plates, which can improve the suppression effect on the current collapse phenomenon.

### Modified Example 2

FIG. 7 is a cross-sectional view showing a schematic structure of a semiconductor device according to a modified example 2. In FIG. 7, the same reference numerals are given to the same components as those of the above mentioned semiconductor device 1 and the detailed description thereof is omitted.

As illustrated in FIG. 7, in the semiconductor device 10b according to the modified example 2, each of the field plates 21 and 23 is formed by one conductive member 50 and each of the field plates 20 and 22 is formed by a plurality of conductive members 50. The plural conductive members 50 are arranged side by side in the width direction W, similarly to the modified example 1.

In the field plate 20, the two conductive members 50 closest to the source electrode 13 are electrically coupled to the gate pad 31 and the remaining one conductive member 50 is electrically coupled to the field plate pad 34.

The field plate 21 is electrically coupled to the field plate pad 34.

In the field plate 22, the two conductive members 50 closest to the source electrode 13 are electrically coupled to the field plate pad 35, and the remaining one conductive member 50 is electrically coupled to the field plate pad 36.

The field plate 23 is also electrically coupled to the field plate pad 36.

Also in the modified example 2, similarly to the modified example 1, the width and the thickness of the conductive members 50 are identical. Therefore, when forming the field plates 20 and 22, trenches 41 and 44 each include three trenches with the same opening width and depth are formed and the conductive member 50 is embedded within the trenches. On the other hand, the field plates 21 and 23 are formed in the same way as the above mentioned embodiment.

According to the semiconductor device 10b in the above mentioned modified example 2, similarly to the above mentioned semiconductor device 10, there is no separate interlayer insulating film between the field plate 22 and the field plate 23. According to this, also in the modified example 2, the number of the interfaces of the interlayer insulating film is less than the number of the steps of the field plates, which can improve the suppression effect on the current collapse phenomenon.

### Modified Example 3

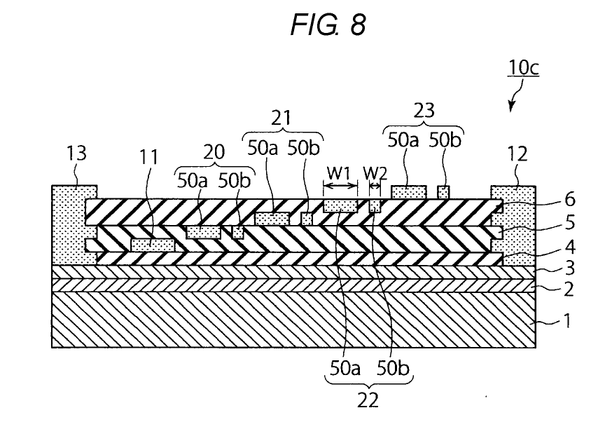

FIG. 8 is a cross-sectional view showing a schematic structure of a semiconductor device according to a modified example 3. In FIG. 8, the same reference numerals are given to the same components as those of the above mentioned semiconductor device 1 and the detailed description thereof is omitted.

As illustrated in FIG. 8, in the semiconductor device 10c according to the modified example 3, each of the field plates 20 to 23 includes two conductive members 50a and 50b, and the two conductive members 50a and 50b are arranged side by side in the width direction.

The width W1 of the conductive member 50a is larger than the width W2 of the conductive member 50b. In the modified example 3, the thickness of the conductive member 50a is equal to the thickness of the conductive member 50b. Therefore, when forming the field plates 20 and 22, trenches 41 and 44 each including two trenches with different opening widths and the same depth are formed and the conductive members 50a and 50b are embedded within the respective trenches. On the other hand, when forming the field plates 21 and 23, the conductive members 50a and 50b with the different width and the same thickness are formed on the interlayer insulating films 5 and 6.

In the field plate 20, the conductive member 50a is electrically coupled to the gate pad 31 and the conductive member 50b is electrically coupled to the field plate pad 34.

In the field plate 21, the conductive member 50a is electrically coupled to the field plate pad 34 and the conductive member 50b is electrically coupled to the field plate pad 35.

In the field plate 22, the conductive member 50a is electrically coupled to the field plate pad 35, and the conductive member 50b is electrically coupled to the field plate pad 36.

The two conductive members 50a and 50b forming the field plate 23 are also electrically coupled to the field plate pad 36.

According to the semiconductor device 10c in the above mentioned modified example 3, similarly to the above mentioned semiconductor device 10, there is no separate interlayer insulating film between the field plate 22 and the field plate 23. According to this, also in the modified example 3, the number of the number of interfaces of the interlayer insulating film is less than the number of the steps of the field plate, which can improve the suppression effect on the current collapse phenomenon.

In the modified example 3, each of the field plates 20 to 23 is formed by the two conductive members 50a and 50b with the different width; however, it may be formed by three and more conductive members. Further, in each of the field plates 20 to 23, the wide conductive member 50a is positioned closer to the source electrode 13 and the narrow conductive member 50b is positioned closer to the drain electrode 13; however, the arrangement may be inverted.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

What is claimed is:

1. A semiconductor device comprising:
a first nitride semiconductor layer;
a second nitride semiconductor layer with a larger band gap than that of the first nitride semiconductor layer, located over the first nitride semiconductor layer;
a gate electrode located over the second nitride semiconductor layer;
a drain electrode and a source electrode provided on the second nitride semiconductor layer and spaced from one another with the gate electrode interposed therebetween;
a plurality of interlayer insulating film layers located over the second nitride semiconductor layer; and
a plurality of field plates, including a first field plate located farther from the second nitride semiconductor layer than the gate electrode and closer to the drain electrode than the gate electrode, and a second field plate located farther from the second nitride semiconductor layer than the first field plate and closer to the drain electrode than the first field plate, wherein
the first field plate and the second field plate extend inwardly of the same interlayer insulating film layer.

2. The device according to claim 1, wherein
the interlayer insulating film layers include a first interlayer insulating film layer covering the gate electrode and a second interlayer insulating film located on the first interlayer insulating film,
the second interlayer insulating film includes a recess extending into the upper surface thereof and inwardly thereof in the direction of the first insulating film, and
the first field plate is located between the first interlayer insulating film and the second interlayer insulating film, and the second field plate is located within the recess.

3. The device according to claim 2, wherein
each of the first field plate and the second field plate comprise a plurality of conductive members, and the conductive members are arranged side by side in a width direction extending between the source electrode and the drain electrode.

4. The device according to claim 2, wherein
the first field plate is formed by one conductive member,
the second field plate is formed by a plurality of conductive members, and the plurality of conductive members are spaced apart in the width direction.

5. The device according to claim 3, wherein
the width of the conductive members is different.

6. The device according to claim 1, further comprising:
a gate pad electrically coupled to the gate electrode, a drain pad electrically coupled to the drain electrode, a source pad electrically coupled to the source electrode, and a plurality of field plate pads, each of the field plate pads electrically coupled to at least one of the field plates, wherein
the electrical potential of the field plate pads is the same as that of the gate pad or the source pad, or is a floating potential.

7. The device according to claim 1, wherein:
the plurality of interlayer insulating film layers comprise a first interlayer insulating film layer and a second interlayer insulating film layer;
the first field plate and the second field plate extend inwardly of the first interlayer insulating layer on opposite sides thereof; and
a third field plate and a fourth field plate extend inwardly of the second interlayer insulating film layer on opposite sides thereof.

8. The semiconductor device according to claim 7, wherein the third field plate overlies and contacts the second field plate.

9. The semiconductor device according to claim 7, wherein each of the plurality of interlayer insulating film layers contact another of the plurality of interlayer insulating film layers to form an interface therebetween; and
the number of interfaces is less than the number of field plates.

10. A semiconductor device, comprising
a substrate;
a first nitride semiconductor layer located over the substrate;
a second nitride semiconductor layer with a larger band gap than that of the first nitride semiconductor layer, located over the first nitride semiconductor layer;
a gate electrode located over the second nitride semiconductor layer;
a drain electrode and a source electrode provided on the second nitride semiconductor layer and spaced from one another with the gate electrode interposed therebetween;
a plurality of interlayer insulating film layers located over the second nitride semiconductor layer, each of the plurality of interlayer insulating film layers contacting another of the plurality of interlayer insulating film layers to form an interface therebetween; and
a plurality of field plates, wherein
the number of interfaces between the plurality of interlayer insulating film layers is less than the number of field plates.

11. The semiconductor device according to claim 10, wherein the plurality of interlayer insulating film layers includes a first interlayer insulating film layer extending between the source electrode and the drain electrode and having a first surface facing the substrate and a second surface facing away from the substrate; and
a first field plate extending inwardly of the first surface of the first interlayer insulating film layer and a second field plate extending inwardly of the second surface of the interlayer insulating film layer, wherein
one of the first and the second field plates is located closer to the source electrode than the other of the first and second field plates.

12. The semiconductor device according to claim 11, wherein the plurality of interlayer insulating film layers further comprise a second interlayer insulating film layer overlying and contacting the first interlayer insulating film layer and forming an interface therebetween, the second interlayer insulating film layer extending between the source electrode and the drain electrode and having a first surface facing the substrate and a second surface facing away from the substrate; and
a third field plate electrode extending inwardly of the first surface of the second interlayer insulating film.

13. The semiconductor device according to claim 12, further comprising a fourth field plate extending inwardly of the second surface of the second interlayer insulating film layer, wherein one of the third and the fourth field plates is located closer to the source electrode than the other of the third and the fourth field plates.

14. The semiconductor device according to claim 13, wherein the second and the third field plates contact each other.

15. The semiconductor device according to claim 13, wherein at least one of the first through fourth field plates comprise a first sub-plate and a second sub-plate.

16. The semiconductor device according to claim 15, wherein the first and second sub-plates are spaced apart in a width direction extending between the source electrode and the drain electrode, and at least one of the first and second sub-plates is larger in the width direction than the other of the first and second sub-plates.

17. The semiconductor device according to claim 10, wherein the first and second field plates comprise a metal.

18. A semiconductor device, comprising
a substrate;
a first nitride semiconductor layer located over the substrate;
a second nitride semiconductor layer with a larger band gap than that of the first nitride semiconductor layer, located over the first nitride semiconductor layer;
a gate electrode located over the second nitride semiconductor layer;
a drain electrode and a source electrode provided on the second nitride semiconductor layer and spaced from one another with the gate electrode interposed therebetween;
a plurality of interlayer insulating film layers located over the second nitride semiconductor layer, each of the plurality of interlayer insulating film layers contacting another of the plurality of interlayer insulating film layers; and
a plurality of field plates, wherein
at least two of the plurality of interlayer insulating film layers include a first surface facing the substrate and a second surface facing away from the substrate, and each of the plurality of insulating film layers include a first field plate extending inwardly of the first surface thereof and a second field plate extending inwardly of the second surface thereof.

19. The semiconductor device according to claim 18, wherein at least one of the first and second field plates is located closer to the source electrode than the other of the first and second field plates.

20. The semiconductor device according to claim 18, wherein a second field plate in one of the plurality of interlayer insulating film layers contacts a first field plate in another of the plurality of interlayer insulating film layers.
